(19) United States
(12) Patent Application Publication
(10) Pub. No.: US 2025/0065360 A1
(43) Pub. Date: Feb. 27, 2025

(54) CONTROL DEVICE AND SUBSTRATE PROCESSING APPARATUS INCLUDING THE SAME

(71) Applicants: SEMES CO., LTD., Cheonan-si (KR); Samsung Electronics Co., Ltd., Suwon-si (KR)

(72) Inventors: Jin Yeong Sung, Gyeonggi-do (KR); Ki Hoon Choi, Chungcheongnam-do (KR); Seung Un Oh, Chungcheongnam-do (KR); Young Ho Park, Incheon (KR); Sang Hyeon Ryu, Gyeonggi-do (KR); Jang Jin Lee, Seoul (KR); Hyun Yoon, Seoul (KR); Sang Gun Lee, Seoul (KR); Yu Jin Cho, Gyeonggi-do (KR); Ho Jong Hwang, Gyeonggi-do (KR); Jong Ju Park, Suwon-si (KR); Jong Keun Oh, Suwon-si (KR); Yong Woo Kim, Suwon-si (KR)

(21) Appl. No.: 18/768,956

(22) Filed: Jul. 10, 2024

(30) Foreign Application Priority Data
Aug. 23, 2023 (KR) 10-2023-0110603

(51) Int. Cl. B05C 13/00; G05B 19/401; G05B 19/404; G06T 7/73

(52) U.S. Cl. CPC B05C 13/00; G05B 19/401; G05B 19/404; G06T 7/74

(57) ABSTRACT

A control device and a substrate processing apparatus including the same are provided. The substrate processing apparatus includes: a support unit including a spin head and configured to support and to rotate a substrate; a spraying unit configured to spray processing liquid onto the substrate; a correction unit in a swing arm, the correction unit configured to move to a target point on the substrate and to irradiate a beam when the processing liquid is sprayed onto the substrate; and a control unit configured to calculate the target point, wherein the control unit is configured to convert image coordinates associated with a first coordinate system and then to calculate the target point by converting the image coordinates associated with the first coordinate system into image coordinates associated with a second coordinate system, and the second coordinate system is based on rotation angles of the spin head and the swing arm.

### CROSS-REFERENCE TO RELATED APPLICATION

This application claims priority under 35 U.S.C. 119 from Korean Patent Application No. 10-2023-0110603, filed on Aug. 23, 2023 in the Korean Intellectual Property Office, the entire contents of which are herein incorporated by reference.

### BACKGROUND

The present disclosure relates to a method of calculating coordinates on a substrate in a substrate processing apparatus that includes a swing stage, a computer program for executing the method, and a substrate processing apparatus including a control device equipped with a processor for running the computer program.

In a photolithography process, a photomask can be used to form circuit patterns on semiconductor devices. To produce semiconductor devices with high precision and uniformity, the pattern linewidth of the semiconductor devices can be identified, and the critical dimension (CD) of the photomask can be corrected.

Equipment for correcting the CD of the photomask may use a swing stage instead of a conventional X/Y stage due to spatial issues within a chamber and the risk of contamination. Therefore, there is a difficulty in precisely aligning a desired point on the photomask with a laser beam.

### SUMMARY

Aspects of the present disclosure provide a control device that can precisely calculate the coordinates of a desired point on a substrate in a swing stage, and a substrate processing apparatus including the control device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate processing apparatus includes: a support unit including a spin head and configured to support and to rotate a substrate; a spraying unit configured to spray processing liquid onto the substrate; a correction unit in a swing arm, the correction unit configured to move to a target point on the substrate and to irradiate a beam when the processing liquid is sprayed onto the substrate; and a control unit configured to calculate the target point, wherein the control unit is configured to convert image coordinates associated with a first coordinate system and then to calculate the target point by converting the image coordinates associated with the first coordinate system into image coordinates associated with a second coordinate system and the second coordinate system is based on rotation angles of the spin head and the swing arm.

According to another aspect of the present disclosure, a control device for calculating a target point on a substrate using a swing arm and a spin head, which are in a substrate processing apparatus. The control device is configured to convert image coordinates associated with a first coordinate system, to convert the image coordinates associated with the first coordinate system into image coordinates associated with a second coordinate system, and to calculate the target point by reflecting an offset associated with a movement direction of the spin head in the image coordinates associated with the second coordinate system, and the second coordinate system is based on rotation angles of the spin head and the swing arm.

According to another aspect of the present disclosure, a substrate processing apparatus includes: a support unit including a spin head and configured to support and to rotate a substrate; a spraying unit configured to spray processing liquid onto the substrate; a correction unit in a swing arm, the correction unit configured to move to a target point on the substrate and to irradiate a beam when the processing liquid is sprayed onto the substrate; and a control unit configured to determine the target point, wherein the control unit is configured to convert image coordinates associated with a first coordinate system, using an affine transformation, to convert the image coordinates associated with the first coordinate system into image coordinates associated with a second coordinate system, and to determine the target point by reflecting an offset associated with a movement direction of the spin head and an offset associated with a movement direction of the swing arm in the image coordinates associated with the second coordinate system, the second coordinate system is based on rotation angles of the spin head and the swing arm, and the control unit is configured to determine the target point using coordinates of an alignment key, on the substrate, by measuring first coordinates and second coordinates of the alignment key at a first point and a second point where the alignment key intersects the swing arm, and converting values derived from the first coordinates and second coordinates and thereby calculating coordinates of an alignment key with its levelness corrected.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram illustrating the internal configuration of a substrate processing apparatus;

FIG. 2 is a first example schematic diagram for explaining the internal configuration of the substrate processing apparatus;

FIG. 3 is a second example schematic diagram for explaining the internal configuration of the substrate processing apparatus;

FIG. 4 is an example schematic diagram for explaining the internal configuration of the correction unit within the substrate processing apparatus;

FIG. 5 is a flowchart for explaining a method for calculating the coordinates of alignment keys on a mask using the substrate processing apparatus;

FIG. 6 is an example schematic diagram for explaining the alignment keys on the mask;

FIG. 7 is a first example schematic diagram for explaining the conversion of reference coordinates as performed in the method of FIG. 5;

FIG. 8 is a second example schematic diagram for explaining the conversion of reference coordinates as performed in the method of FIG. 5;

FIG. 9 is a third example schematic diagram for explaining the conversion of reference coordinate as performed in the method of FIG. 5;

FIG. 10 is a fourth example schematic diagram for the conversion of reference coordinates as performed in the method of FIG. 5;

FIG. 11 is a first example schematic diagram for explaining the intersection points between the alignment keys on the mask and a swing arm;

FIG. 12 is a second example schematic diagram for explaining the intersection points between the alignment keys on the mask and the swing arm;

FIG. 13 is a first example flowchart for explaining a method of measuring an alignment key using reference coordinates;

FIG. 14 is a first example schematic diagram for explaining the conversion of an alignment key into equipment coordinates;

FIG. 15 is a second example flowchart for explaining the method of measuring an alignment key using reference coordinates;

FIG. 16 is a second example schematic diagram for explaining the conversion of an alignment key into equipment coordinates;

FIG. 17 is an example schematic diagram for explaining the correction of a coordinate transformation formula as performed in the method of FIG. 5; and

FIG. 18 is a flowchart for explaining a method of converting the coordinates of a target point on the mask to coordinates in the substrate processing apparatus.

### DETAILED DESCRIPTION

Embodiments of the present disclosure will be described with reference to the attached drawings. The same reference numerals are used for the same components in the drawings, and redundant descriptions thereof may be omitted in the interest of brevity.

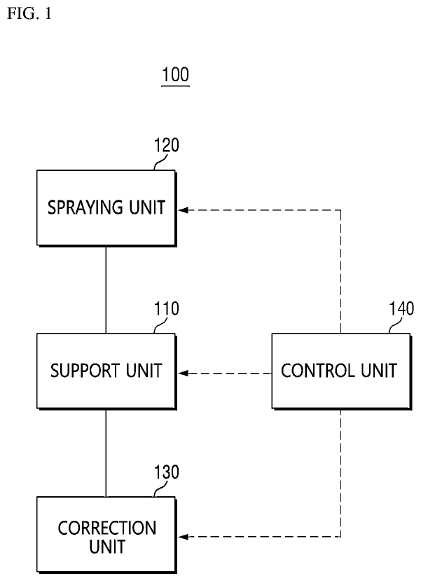

FIG. 1 is a block diagram illustrating the internal configuration of a substrate processing apparatus. Referring to FIG. 1, a substrate processing apparatus 100 may include a support or a support unit 110, a sprayer or a spraying unit 120, a correction unit 130, and a controller or control unit 140.

The substrate processing apparatus 100 may perform a wet cleaning process on a substrate. Alternatively, the substrate processing apparatus 100 may perform a wet etching process on a substrate. The substrate processing apparatus 100 may be applicable to a photolithography process.

The substrate processing apparatus 100 may correct the critical dimension (CD) of a substrate using a beam. For example, the substrate processing apparatus 100 may use an extreme ultraviolet (EUV) beam to correct CD. For example, the substrate processing apparatus 100 may correct the CD of a photomask.

The support unit 110 may support a substrate when processing the substrate. The support unit 110 may support a substrate when spraying chemicals on the substrate. The support unit 110 may support a substrate when correcting the CD of the substrate using a beam.

The support unit 110 may be provided as a swing-type stage. The support unit 110 may include a rotation chuck. For example, the support unit 110 may be configured to include a spin head 221, a rotating shaft or a rotation shaft 222, a rotation drive part 223, support pins 224, and guide pins 225.

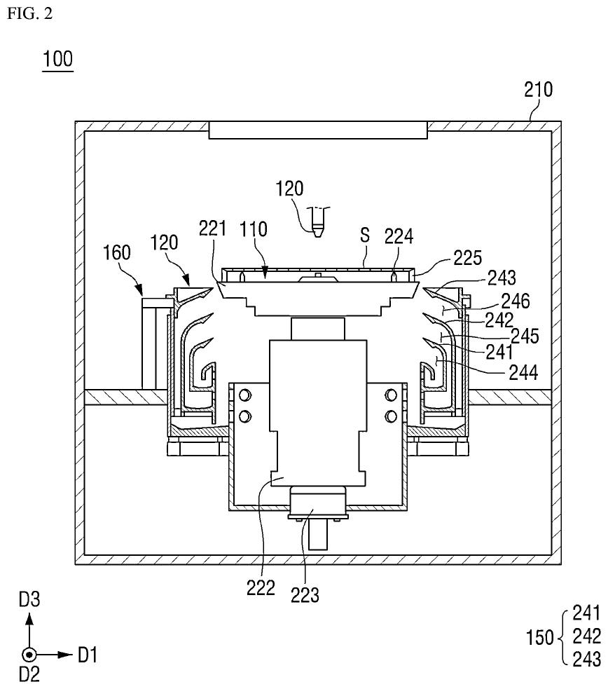

FIG. 2 is a first example schematic diagram for explaining the internal configuration of the substrate processing apparatus. The following description refers to FIG. 2.

Referring to FIG. 2, first and second directions D1 and D2 form a plane. For example, the first direction D1 may be a front-rear direction, and the second direction D2 may be a left-right direction. Alternatively, the first direction D1 may be the left-right direction, and the second direction D2 may be the front-rear direction. A third direction D3 is the height direction and is perpendicular to the plane formed by the first and second directions D1 and D2.

The support unit 110 may be provided within a chamber housing 210. The spraying unit 120 and the correction unit 130 may be provided on the chamber housing 210. The chamber housing 210 may provide space for processing a substrate S. However, the present disclosure is not limited thereto. Alternatively, the support unit 110, the spraying unit 120, and the correction unit 130 may all be provided within the chamber housing 210.

The spin head 221 may be provided to accommodate the substrate S thereon. The spin head 221 may rotate according to the operation of the rotating shaft 222. The substrate S may rotate together with the spin head 221 while being seated on the spin head 221. The spin head 221 may rotate clockwise. Alternatively, the spin head 221 may rotate counterclockwise.

The spin head 221 may have a different cross-sectional shape from the substrate S. For example, the spin head 221 may have a circular cross-sectional shape, while the substrate S may have a rectangular cross-sectional shape. However, the present disclosure is not limited to this example. Alternatively, the spin head 221 may have the same cross-sectional shape as the substrate S.

The rotating shaft 222 may generate rotational force using the electrical energy provided from the rotation drive part 223. The rotating shaft 222 may provide rotational force to the spin head 221 to rotate the spin head 221.

The support pins 224 and the guide pins 225 may fix the substrate S on the spin head 221. The support pins 224 may support the bottom surface of the substrate S on the spin head 221. The support pins 224 may support the bottom surface of the substrate S so that the substrate S may not contact the top surface of the spin head 221. The guide pins 225 may support the side or edge of the substrate S on the spin head 221. The guide pins 225 may support the side of the substrate S to prevent the substrate S from being detached from the spin head 221 when the spin head 221 rotates. The guide pins 225 may function as chucking pins. A plurality of support pins 224 and a plurality of guide pins 225 may be provided on the spin head 221, but the present disclosure is not limited thereto. The support pins 224 and the guide pins 225 may be disposed to have or define an annular ring shape.

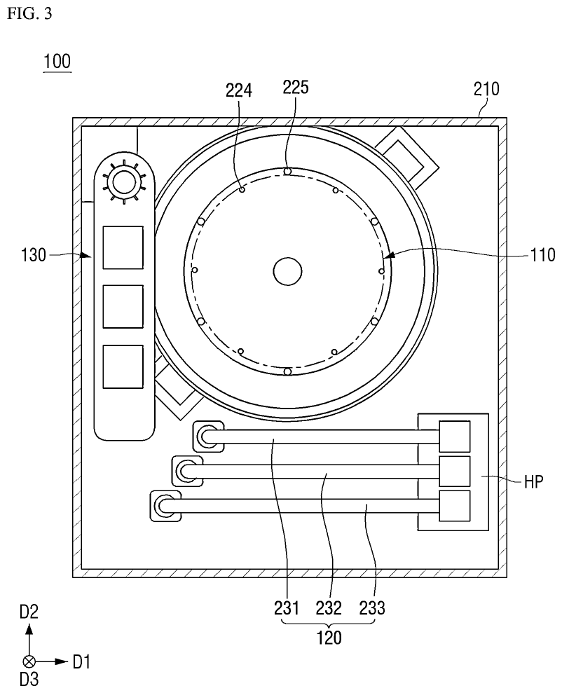

Referring back to FIG. 1, the spraying unit 120 sprays a processing liquid onto the substrate S. The spraying unit 120 may include a plurality of nozzles, but the present disclosure is not limited thereto. Alternatively, the spraying unit 120 may include a single nozzle. In a case where the spraying unit 120 includes a plurality of nozzles, the nozzles may spray different processing liquids. For example, the spraying unit 120 may include a first nozzle 231, a second nozzle 232, and a third nozzle 233 (see for example FIG. 3).

FIG. 3 is a second example schematic diagram for explaining the internal configuration of the substrate processing apparatus. The following description refers to FIG. 3.

Referring to FIG. 3, the first, second, and third nozzles 231, 232, and 233 may move to a process position or a home port HP. The process position refers to an upper area of the substrate S. After moving to the process position, the first, second, and third nozzles 231, 232, and 233 may spray processing liquids onto the substrate S. The home port HP is disposed in an outer area beyond the top of the substrate S. After spraying the processing liquids on the substrate S, the first, second, and third nozzles 231, 232, and 233 may move to the home port HP to wait.

The first, second, and third nozzles 231, 232, and 233 may rotate to move from the process position to the home port HP. After rotating, the first, second, and third nozzles 231, 232, and 233 may elevate at the home port HP. The first, second, and third nozzles 231, 232, and 233 may elevate at the process position and then rotate.

The first, second, and third nozzles 231, 232, and 233 may rotate to move from the home port HP to the process position. After rotating, the first, second, and third nozzles 231, 232, and 233 may elevate at the process position. The first, second, and third nozzles 231, 232, and 233 may elevate at the home port HP and then rotate.

The first nozzle 231 may spray a first processing liquid. The second nozzle 232 may spray a second processing liquid. The third nozzle 233 may spray a third processing liquid. The first, second, and third processing liquids may contain or include the same material. Alternatively, the first, second, and third processing liquids may contain or include different materials. Yet alternatively, some of the first, second, and third processing liquids may contain or include the same material, and the rest may contain or include a different material.

The first processing liquid may be an alkaline solution. For example, the first nozzle 231 may spray the Standard Cleaning 1 (SC-1). The SC-1 may be a hydrogenous solution containing hydrogen peroxide (H₂O₂) and ammonium hydroxide (NH₄OH). The second processing liquid may be a hydrogenous solution diluted with an alkaline chemical. For example, the second nozzle 232 may spray hydrogen water (H₂W). The first and second processing liquids may be provided simultaneously on the substrate S, but the present disclosure is not limited thereto. Alternatively, the first and second processing liquids may be sequentially provided on the substrate S. The third processing liquid may be a rinse liquid. For example, the third nozzle 233 may spray deionized water (DIW).

Although not illustrated in FIG. 1, the substrate processing apparatus 100 may further include a collection unit 150 and an elevation unit 160. The following description refers to FIG. 2.

Referring to FIG. 2, the collection unit 150 may be provided to surround the support unit 110. The collection unit 150 may collect the processing liquids used in processing or treating the substrate S. When the substrate S is fixed on the support unit 110 and the support unit 110 rotates, the spraying unit 120 may spray the processing liquids onto the substrate S. The processing liquids discharged onto the substrate S may be flung toward the direction where the collection unit 150 is located, due to the centrifugal force generated by the rotation of the support unit 110. The collection unit 150 may collect the processing liquids scattered in all directions, through inlets.

The collection unit 150 may be configured to include a plurality of collection ducts. The collection unit 150 may collect different types of processing liquids into different collection ducts, enabling the reuse of the processing liquids. For example, the collection unit 150 may include a first collection duct 241, a second collection duct 242, and a third collection duct 243. The first, second, and third collection ducts 241, 242, and 243 may have a bowl shape.

The first, second, and third collection ducts 241, 242, and 243 may collect different types of processing liquids. For example, the first collection duct 241 may collect the rinse liquid, the second collection duct 242 may collect the first processing liquid, and the third collection duct 243 may collect the second processing liquid. The first collection duct 241 may collect the rinse liquid through a first inlet 244. The second collection duct 242 may collect the first processing liquid through a second inlet 245. The third collection duct 243 may collect the second processing liquid through a third inlet 246.

Although not illustrated in FIG. 2, the first, second, and third collection ducts 241, 242, and 243 may be connected to their respective recovery lines. The processing liquids collected through the first, second, and third collection ducts 241, 242, and 243 may be made reusable through a processing liquid regeneration unit.

The first, second, and third collection ducts 241, 242, and 243 may be provided in an annular ring shape. The first collection duct 241 may be installed to surround the support unit 110. The second collection duct 242 may be installed to surround the first collection duct 241. The third collection duct 243 may be installed to surround the second collection duct 242.

Meanwhile, if the spraying unit 120 includes a single nozzle, the collection unit 150 may include a single collection duct. The collection unit 150 may be equipped with as many collection ducts as there are nozzles in the spraying unit 120.

The elevation unit 160 may lift the collection unit 150. The elevation unit 160 may simultaneously lift the first, second, and third collection ducts 241, 242, and 243. Depending on the types of the processing liquids, the elevation unit 160 may adjust the height of the collection unit 150 so that the processing liquids may be collected into the respective collection ducts 241, 242, and 243 through the respective inlets 244, 245, and 246.

Referring back to FIG. 1, the correction unit 130 may correct information related to pattern elements formed on the substrate S, using a beam. For example, the correction unit 130 may correct the CD of the pattern elements using a laser beam. A mask will hereinafter be described as being an example of the substrate S, but the present disclosure is not limited thereto.

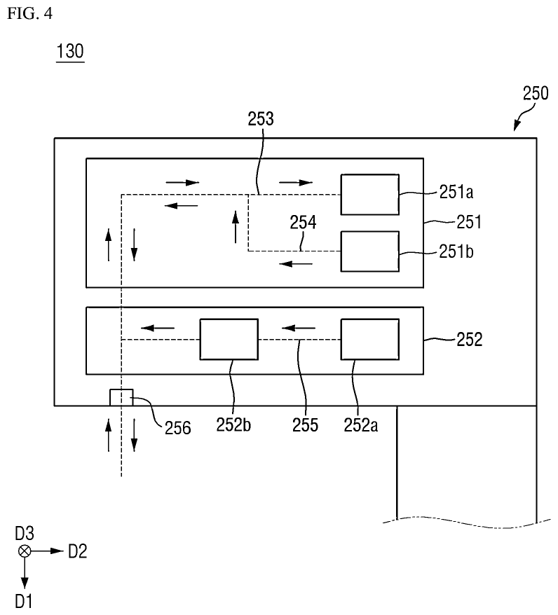

The correction unit 130 may be configured to include an image acquisition module 251 and a beam irradiation module 252 to correct the CD of pattern elements formed on the mask. The image acquisition module 251 and the beam irradiation module 252 may be mounted within a swing arm 250 (see for example FIG. 4).

FIG. 4 is an example schematic diagram for explaining the internal configuration of the correction unit within the substrate processing apparatus. The following description refers to FIG. 4.

The image acquisition module 251 may acquire a surface image of the mask. The surface image of the mask may include the shape of patterns formed on the mask. Using the surface image of the mask, the linewidth of the patterns formed on the mask can be identified.

The image acquisition module 251 may be configured as a vision system that includes a vision camera. The image acquisition module 251 may include a camera sensor 251a and a lamp or light source 251b. The lamp 251b may illuminate the surface of the mask along a second optical path 254. The lamp 251b may be provided as, for example, a light-emitting diode (LED) lamp. The camera sensor 251a may acquire the surface image of the mask while the lamp 251b is operating. The camera sensor 251a may acquire the surface image of the mask based on an optical signal that enters through a light inlet 256 and travels along a first optical path 253. Although not illustrated in FIG. 4, the image acquisition module 251 may further include lenses, mirrors, etc., along the first and second optical paths 253 and 254.

The beam irradiation module 252 may irradiate a laser beam onto the surface of the mask. For example, the beam irradiation module 252 may irradiate an EUV beam. The beam irradiation module 252 may irradiate the laser beam onto the mask when a processing liquid is provided on the mask. The beam irradiation module 252 may irradiate the laser beam along the third optical path 255.

The beam irradiation module 252 may locally heat a designated location on the mask based on information provided by the surface image of the mask. The laser beam may activate the processing liquid on the mask, potentially increasing the efficiency of cleaning or etching the mask. The beam irradiation module 252 may adjust the linewidth of the micro-patterns formed on the mask.

The beam irradiation module 252 may be provided as a laser optic module that includes a laser source. The beam irradiation module 252 may include a laser sensor 252a and a beam expander 252b. Additionally, although not illustrated in FIG. 4, the beam irradiation module 252 may further include a beam splitter, mirrors, etc., along a third optical path 255.

Referring back to FIG. 1, the control unit 140 may control the overall operations of the support unit 110, the spraying unit 120, and the correction unit 130. Furthermore, the control unit 140 may also control the overall operations of the collection unit 150 and the elevation unit 160.

The control unit 140 may include a processor that executes control over each of the components of the substrate processing apparatus 100, a network that facilitates wired or wireless communication with each of the components of the substrate processing apparatus 100, and storage module or memory that stores instructions related to functions or operations for controlling each of the components of the substrate processing apparatus 100, processing recipes including instructions, various data, etc. Additionally, the control unit 140 may further include a user interface that includes input features or mechanisms for an operator to manage the substrate processing apparatus 100 through command input operations and output features or mechanisms to visualize and display the operating status of the substrate processing apparatus 100. The control unit 140 may be provided as a computing device for data processing and analysis, command transmission, etc.

The instructions may be provided in the form of a computer program or application. The computer program may include one or more instructions and may be stored on a computer-readable recording medium. The instructions may encompass code generated by a compiler, code executable by an interpreter, etc. The storage module may be provided as one or more storage media selected from among a hard disk drive (HDD), a solid-state drive (SSD), a card-type memory, a random-access memory (RAM), a static RAM (SRAM), a read-only memory (ROM), an electrically erasable programmable ROM (EEPROM), a programmable ROM (PROM), a magnetic memory, a magnetic disk, and an optical disk.

For the beam irradiation module 252 to precisely target a desired point on the mask, alignment keys on the mask may be measured with the camera sensor 251a of the image acquisition module 251.

However, since the substrate processing apparatus 100 uses a swing stage instead of a conventional X/Y stage, coordinate conversion is needed. The X/Y coordinates of the mask may be determined based on the fixed length of the swing arm 250, the position of the rotation center of the spin head 221, etc., and may then be converted to the θ/φ coordinate system of equipment, i.e., the substrate processing apparatus 100, or vice versa.

When converting to the θ/φ coordinate system of the substrate processing apparatus 100, the same location may be measured in two independent coordinate systems. These two independent coordinate systems may be symmetrical with respect to a straight line connecting the rotation center of the swing arm 250 and the rotation center of the spin head 221. Ideally, when perfectly aligned, the substrate processing apparatus 100 can accurately convert the desired location between the two coordinate systems.

However, realistically, various environmental factors such as misalignment when placing the mask, assembly tolerances of the components of the substrate processing apparatus 100, and the accuracy of rotation motors may lead to errors during coordinate conversion. Applying an affine transformation after converting to a single coordinate system, as with a conventional X/Y stage, may not be able to achieve the necessary precision for processing.

To address this problem, the alignment keys may be measured not only in a first quadrant coordinate system, where the swing arm 250 passes the center of the spin head 221, but also in a third quadrant coordinate system, where the swing arm 250 does not pass the center of the spin head 221. Thereafter, the alignment keys may be converted to the X/Y coordinate system, averaged, and then affine-transformed.

Due to equipment errors, the average of the values of the alignment keys may differ from the values of the alignment keys in first and third quadrant areas of the coordinate plane. When converting the average of the values of the alignment keys to the coordinate system of the substrate processing apparatus 100, directional errors may be observed. To correct the directional errors, an offset value for the θ/φ coordinate system may be calculated. The offset value may be added after converting the X/Y coordinates of the desired point on the mask into θ/φ coordinates. In this manner, the coordinates of the desired point on the mask on the swing stage can be accurately calculated.

A method of calculating the coordinates of the desired point on the mask on the swing stage will hereinafter be described. This method may be performed by the control unit 140. Other components of the substrate processing apparatus 100 may operate according to commands from, or under the control of, the control unit 140. This method may be provided as a computer program executable by the control unit 140. The computer program may be stored and provided on a computer-readable recording medium. The computer-readable recording medium may store program code executable by a processor. For example, the computer-readable recording medium may be provided as a portable disk such as an HDD, SSD, CD-ROM or DVD or as a semiconductor memory such as a flash memory.

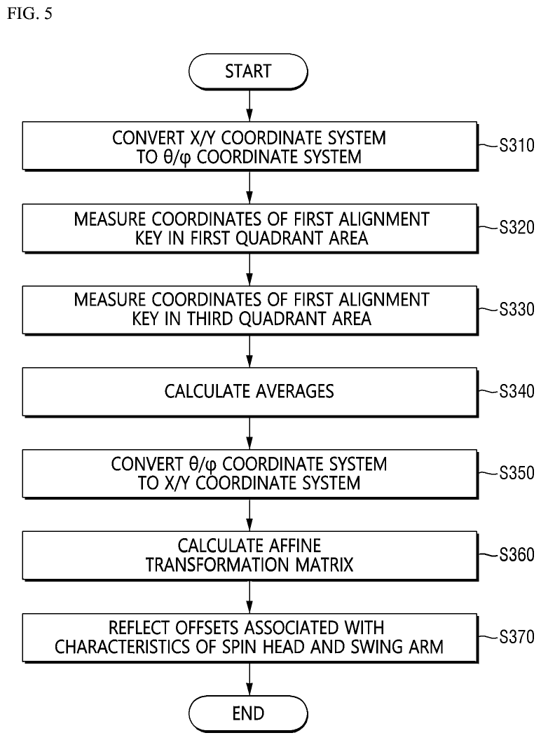

FIG. 5 is a flowchart for explaining a method for calculating the coordinates of alignment keys on a mask using the substrate processing apparatus. The following description refers to FIG. 5.

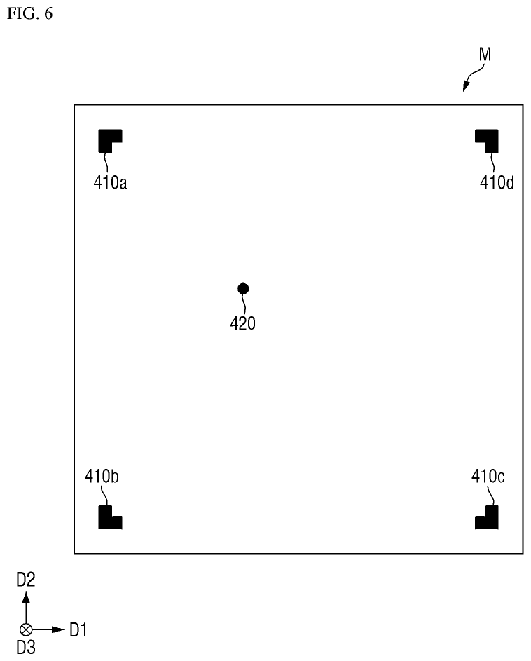

Referring to FIG. 5, the coordinates of the desired point on the mask may be calculated based on a plurality of alignment keys disposed on sides of the mask. For example, referring to FIG. 6, a mask M may include four alignment keys that are respectively disposed near the four corners of the mask M, i.e., first, second, third, and fourth alignment keys 410a, 410b, 410c, and 410d. The coordinates of a desired point 420 on the mask M may be calculated based on the coordinates of at least one of the first, second, third, and fourth alignment keys 410a, 410b, 410c, and 410d. FIG. 6 is an example schematic diagram for explaining the alignment keys on the mask.

It will hereinafter be described how to calculate the coordinates of the first alignment key 410a, and the following description may also be applicable to the calculation of the coordinates of each of the second, third, and fourth alignment keys 410b, 410c, and 410d.

First, the control unit 140 converts the X/Y coordinate system of the mask M to the θ/φ coordinate system of the substrate processing apparatus 100 (S310).

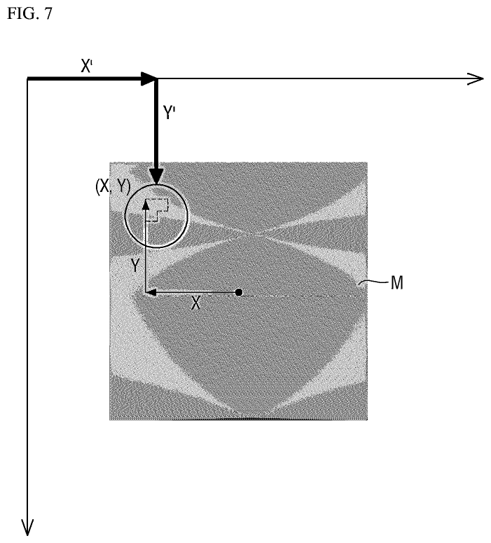

The two-dimensional (2D) coordinates of each point on the mask M may be represented based on the X/Y coordinate system. For example, the coordinates of the first alignment key 410a may be represented as (X, Y) relative to the center of the mask M. The coordinates of the first alignment key 410a may be represented as (X′, Y′) relative to the origin of the substrate processing apparatus 100. FIG. 7 is a first example schematic diagram for explaining the conversion of reference coordinates as performed in the method of FIG. 5.

The substrate processing apparatus 100 does not have a stage based on the X/Y coordinate system. The substrate processing apparatus 100 utilizes a swing-type stage based on the θ/φ coordinate system. The substrate processing apparatus 100 includes two rotating elements, i.e., the spin head 221 and the swing arm 250.

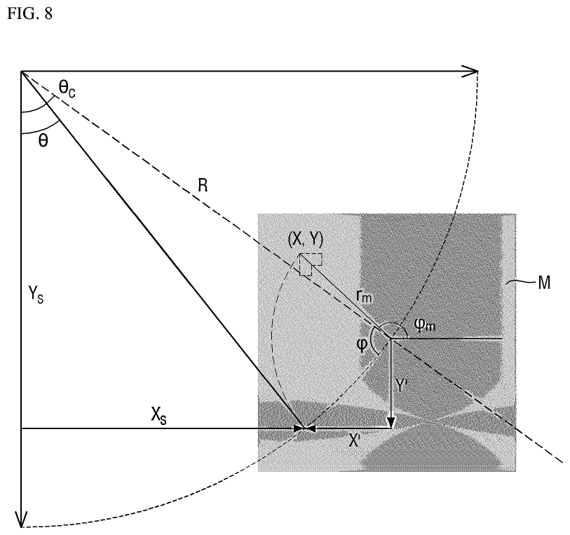

In the substrate processing apparatus 100, the rotation angle (φ) of the spin head 221 and the rotation angle (θ) of the swing arm 250 may be calculated. Using these two degrees of freedom, the coordinates of the first alignment key 410a may be transformed into coordinates in the θ/φ coordinate system of the substrate processing apparatus 100. For example, the rotation angle (θ) of the swing arm 250 and the rotation angle (q) of the spin head 221 may be used to map the coordinates (X, Y) of the first alignment key 410a into coordinates (θ, φ) based on the origin of the substrate processing apparatus 100. The origin of the substrate processing apparatus 100 may be determined based on the rotation axis of the swing arm 250. FIG. 8 is a second example schematic diagram for explaining the conversion of reference coordinates as performed in the method of FIG. 5.

The first alignment key 410a may intersect the light inlet 256 of the swing arm 250 perpendicularly, i.e., in the third direction D3, according to the rotation of the swing arm 250 and the spin head 221. Here, the intersection of the first alignment key 410a and the light inlet 256 in the third direction D3 means that the first alignment key 410a and the light inlet 256 are placed on the same line in the third direction D3. For example, if the spatial coordinates of the first alignment key 410a are (X1, Y1, Z1) and the spatial coordinates of the light inlet 256 are (X2, Y2, Z2), the first alignment key 410a and the light inlet 256 may satisfy the following condition: X1=X2, Y1=Y2, and Z1≠Z2.

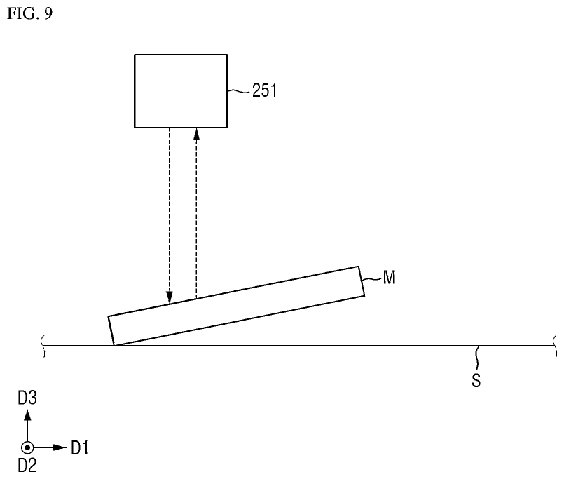

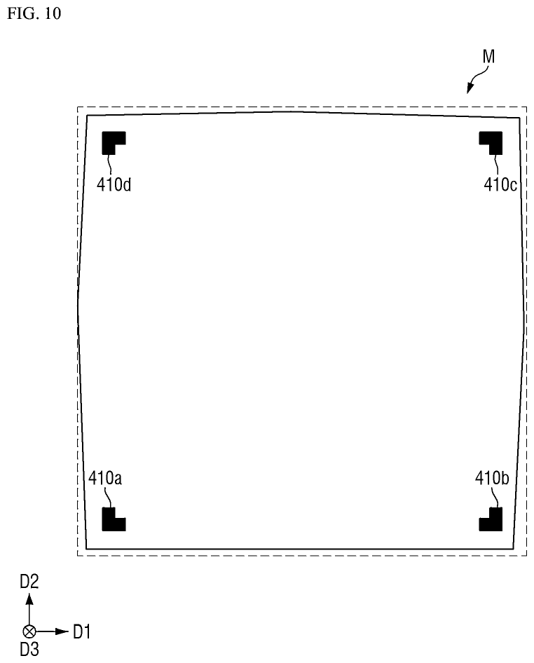

However, referring to FIG. 9, due to various environmental factors such as assembly tolerance among the components within the substrate processing apparatus 100, the mask M may not sit horizontally on a top surface S of the spin head 221. In this case, the image acquisition module 251 may not be able to acquire a rectangular surface image of the mask M. The image acquisition module 251 may acquire a distorted surface image of the mask M. For example, referring to FIG. 10, the image acquisition module 251 may acquire a trapezoidal surface image of the mask M.

Affine transformation cannot correct the levelness of the mask M. If the mask M exhibits both a tilt and rotation at the same time, it may be impossible to precisely target the intersection points between the first alignment key 410a and the light inlet 256. FIG. 9 is a third example schematic diagram for explaining the conversion of reference coordinate as performed in the method of FIG. 5. FIG. 10 is a fourth example schematic diagram for the conversion of reference coordinates as performed in the method of FIG. 5.

The first alignment key 410a may intersect the light inlet 256 of the swing arm 250 in the third direction D3 at two different points, i.e., first and second points, according to the rotation of the swing arm 250 and the spin head 221.

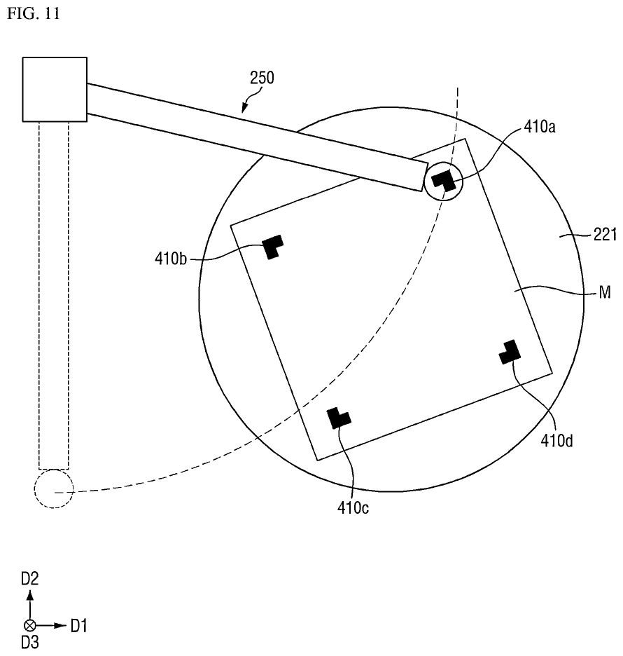

Specifically, the first alignment key 410a may intersect the light inlet 256 of the swing arm 250 in the third direction D3 at the first point. The first alignment key 410a may intersect the light inlet 256 in the first quadrant area where the swing arm 250 passes through the center of the spin head 221. If the top surface S of the spin head 221 is divided into four quadrant areas, i.e., first through fourth quadrant areas, the first point may be located in the first quadrant area. FIG. 11 is a first example schematic diagram for explaining the intersection points between the alignment keys on the mask and the swing arm.

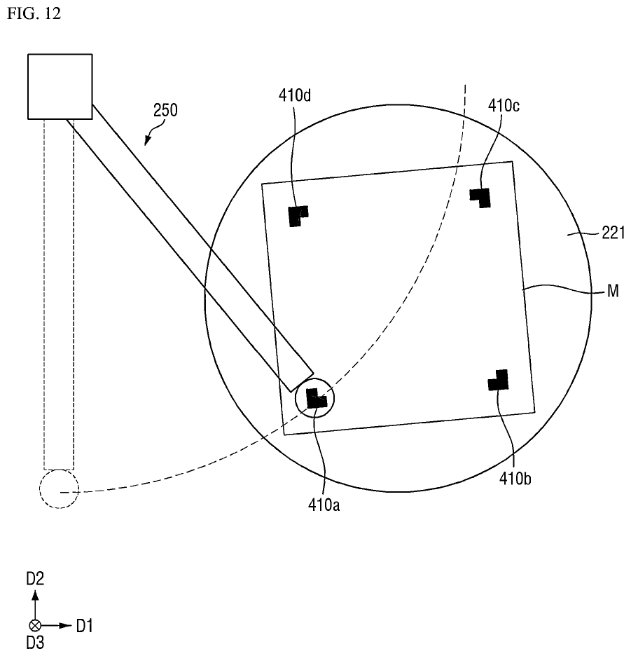

The first alignment key 410a may also intersect the light inlet 256 of the swing arm 250 in the third direction D3 at the second point. The first alignment key 410a may intersect with the light inlet 256 in the third quadrant plane where the swing arm 250 does not pass through the center of the spin head 221. If the top surface S of the spin head 221 is divided into four quadrant areas, i.e., the first through fourth quadrant areas, the second point may be located in the third quadrant area. FIG. 12 is a second example schematic diagram for explaining the intersection points between the alignment keys on the mask and the swing arm.

Referring back to FIG. 5, after converting the reference coordinates from the X/Y coordinate system to the θ/φ coordinate system in step S310, the control unit 140 measures the coordinates of the first alignment key 410a at the first point in the first quadrant area (S320).

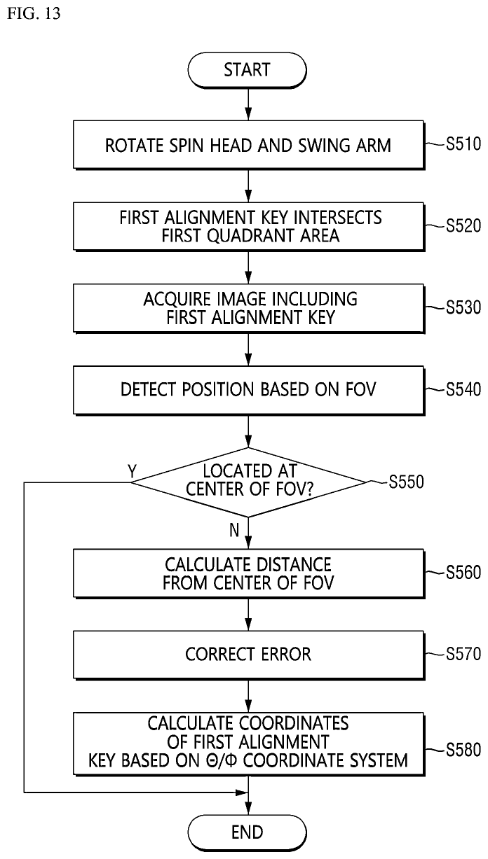

The measurement of the coordinates of the first alignment key 410a at the first point, i.e., step S320, will hereinafter be described. FIG. 13 is a first example flowchart for explaining a method of measuring an alignment key using reference coordinates.

Referring to FIG. 13, the spin head 221 rotates. As the spin head 221 rotates, the mask M, seated on the spin head 221, may rotate, and the swing arm 250 may also rotate (S510) according to the rotation of the spin head 221. The spin head 221 and the swing arm 250 may rotate at the same time, but the present disclosure is not limited thereto. Alternatively, one of the spin head 221 and the swing arm 250 may rotate first, and a predetermined amount of time later, the other may rotate.

As explained earlier with reference to FIG. 11, the first alignment key 410a may intersect the light inlet 256 of the swing arm 250 at the first point within the first quadrant area according to the rotation of both the spin head 221 and the swing arm 250 (S520).

When the first alignment key 410a reaches the first point where the first alignment key 410a intersects the light inlet 256 of the swing arm 250, the image acquisition module 251 acquires a surface image of the mask M that includes the first alignment key 410a, based on the Field of View (FOV) of the camera sensor 251a (S530).

Thereafter, the control unit 140 detects the position of the first alignment key 410a by processing the acquired surface image (S540).

The first alignment key 410a may be located at the center of the FOV of the camera sensor 251a in the acquired surface image (S550). However, if the first alignment key 410a is not located at the center of the FOV (S550), the control unit 140 calculates the distance between the position of the first alignment key 410a and the center of the FOV (S560).

Thereafter, the control unit 140 corrects error based on the distance between the position of the first alignment key 410a and the center of the FOV to align the position of the first alignment key 410a with the center of the FOV (S570). The control unit 140 may repeat the process of correcting error until the position of the first alignment key 410a is aligned with the center of the FOV.

Once the position of the first alignment key 410a is aligned with the center of the FOV, the control unit 140 calculates the coordinates of the first alignment key 410a at the first point within the first quadrant area based on the θ/φ coordinate system (S580). The control unit 140 may calculate the coordinates of the first alignment key 410a at the first point based on the acquired surface image of the mask M, when the first alignment key 410a is positioned at the center of the FOV.

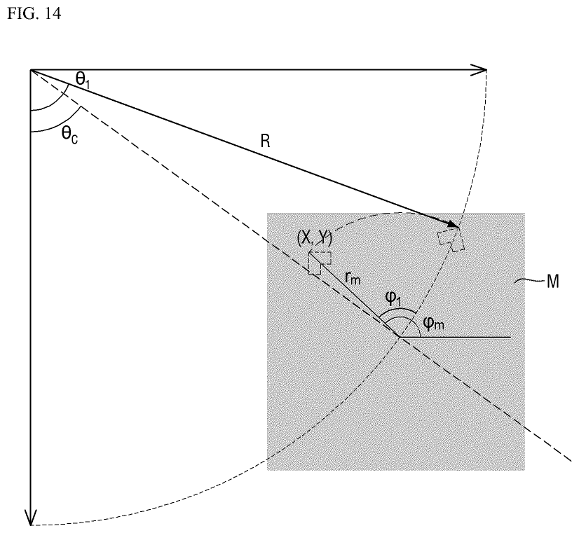

Referring to FIG. 14, the control unit 140 may convert the coordinates (X, Y) of the first alignment key 410a in the X/Y coordinate system into coordinates in the first quadrant coordinate system of the substrate processing apparatus 100, i.e., coordinates (θ1, φ1) in a first θ/φ coordinate system. FIG. 14 is a first example schematic diagram for explaining the conversion of an alignment key into equipment coordinates.

$${θ}_{1} = {θ}_{c} + {cos}^{- 1} ( 1 - {r}_{m}^{2} / 2 {R}^{2} ) \qquad [ Equation 1 ]$$

Referring to Equation 1, θ₁ represents the rotation angle of the swing arm 250, particularly, the rotation angle of the swing arm 250 when the first alignment key 410a and the light inlet 256 intersect in the third direction D3 at the first point, θ_{c} represents the base angle of the swing arm 250, particularly, the rotation angle of the swing arm 250 when the light inlet 256 intersects the center of the mask M in the third direction D3, rₘ represents the distance between the first alignment key 410a and the center of the mask M, and R represents the distance between the first alignment key 410a and the origin of the substrate processing apparatus 100, particularly, the distance between the first alignment key 410a and the origin of the substrate processing apparatus 100 when the first alignment key 410a and the light inlet 256 intersect in the third direction D3 at the first point.

$${φ}_{1} = - {sin}^{- 1} ( - {r}_{m} / 2 R ) - ( {φ}_{m} - {θ}_{c} ) \qquad [ Equation 2 ]$$

Referring to Equation 2, φ₁ represents the rotation angle of the spin head 221, particularly, the rotation angle of the spin head 221, which may be calculated based on the center of the mask M, when the first alignment key 410a moves from a reference point to the first point, and Om represents the base angle of the spin head 221, which may be calculated based on the center of the mask M.

After the measurement of the coordinates of the first alignment key 410a at the first point in the first quadrant area, i.e., step S320, the control unit 140 measures the coordinates of the first alignment key 410a at the second point in the third quadrant area (S330).

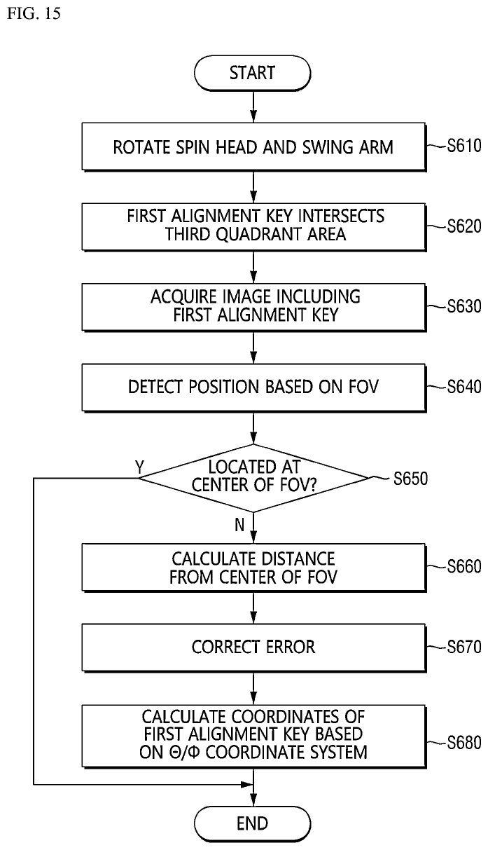

The measurement of the coordinates of the first alignment key 410a at the second point, i.e., step S330, will hereinafter be described with reference to FIG. 15. FIG. 15 is a second example flowchart for explaining the method of measuring an alignment key using reference coordinates.

Referring to FIG. 15, the spin head 221 rotates. As the spin head 221 rotates, the mask M, seated on the spin head 221, may rotate, and the swing arm 250 may also rotate (S610) according to the rotation of the spin head 221. The spin head 221 and the swing arm 250 may rotate at the same time, but the present disclosure is not limited thereto. Alternatively, one of the spin head 221 and the swing arm 250 may rotate first, and a predetermined amount of time later, the other may rotate.

As mentioned earlier with reference to FIG. 12, the first alignment key 410a may intersect the light inlet 256 of the swing arm 250 at the second point within the third quadrant area according to the rotation of both the spin head 221 and the swing arm 250 (S620).

When the first alignment key 410a reaches the second point where the first alignment key 410a intersects the light inlet 256 of the swing arm 250, the image acquisition module 251 acquires a surface image of the mask M that includes the first alignment key 410a, based on the FOV of the camera sensor 251a (S630).

Thereafter, the control unit 140 detects the position of the first alignment key 410a by processing the acquired surface image (S640).

The first alignment key 410a may be located at the center of the FOV of the camera sensor 251a in the acquired surface image (S650). However, if the first alignment key 410a is not located at the center of the FOV (S650), the control unit 140 calculates the distance between the position of the first alignment key 410a and the center of the FOV (S660).

Thereafter, the control unit 140 corrects error based on the distance between the position of the first alignment key 410a and the center of the FOV to align the position of the first alignment key 410a with the center of the FOV (S670). The control unit 140 may repeat the process of correcting error until the position of the first alignment key 410a is aligned with the center of the FOV.

Once the position of the first alignment key 410a is aligned with the center of the FOV, the control unit 140 calculates the coordinates of the first alignment key 410a at the second point within the third quadrant area based on the θ/φ coordinate system (S680). The control unit 140 may calculate the coordinates of the first alignment key 410a at the second point based on the acquired surface image of the mask M, when the first alignment key 410a is positioned at the center of the FOV.

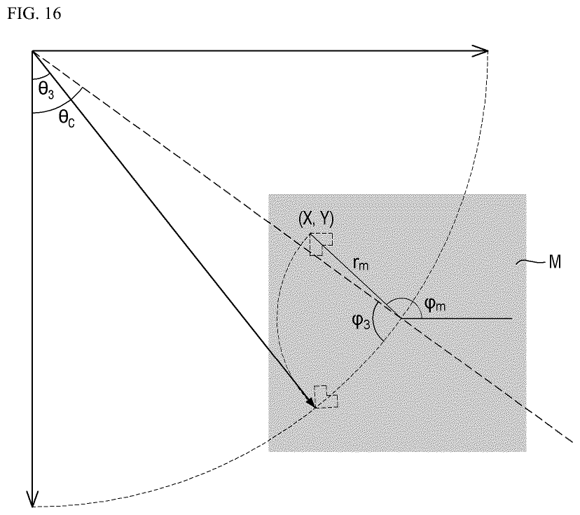

Referring to FIG. 16, the control unit 140 can convert the coordinates (X, Y) of the first alignment key 410a in the X/Y coordinate system into coordinates in the third quadrant coordinate system of the substrate processing apparatus 100, i.e., coordinates (θ2, φ2) in the second θ/φ coordinate system. FIG. 16 is a second example schematic diagram for explaining the conversion of an alignment key into equipment coordinates.

$${θ}_{3} = {θ}_{c} - {cos}^{- 1} ( 1 - {r}_{m}^{2} / 2 {R}^{2} ) \qquad [ Equation 3 ]$$

Referring to Equation 3, θ₃ represents the rotation angle of the swing arm 250, particularly, the rotation angle of the swing arm 250 when the first alignment key 410a and the light inlet 256 intersect perpendicularly (i.e., in the third direction D3) at the second point.

$${φ}_{3} = {cos}^{- 1} ( {r}_{m} / 2 R ) - ( {φ}_{m} - {θ}_{c} - π / 2 ) \qquad [ Equation 4 ]$$

Referring to Equation 4, φ₃ represents the rotation angle of the spin head 221, particularly, the rotation angle of the spin head 221, which may be calculated based on the center of the mask M, when the first alignment key 410a moves from the reference point to the second point.

The measurement of the coordinates of the first alignment key 410a at the first point, i.e., step S320, may be performed before the measurement of the coordinates of the first alignment key 410a at the second point, i.e., step S330, but the present disclosure is not limited thereto. Alternatively, step S320 may be performed after step S330. Further alternatively, steps S320 and S330 may be performed at the same time.

Referring back to FIG. 5, in steps S320 and S330, the coordinates (X, Y) of the first alignment key 410a may be converted into the coordinates (θ1, φ1) and the coordinates (θ2, φ2) based on the origin of the substrate processing apparatus 100, in consideration of the intersection points between the spin head 221 and the swing arm 250 that are rotating. In this manner, the intersection points between the mask M on the spin head 221 and the swing arm 250 can be precisely targeted based on the coordinates (θ1, φ1) and the coordinates (θ2, φ2), even if the tilt and rotation of the mask M both exist.

Thereafter, the control unit 140 calculates the averages of the coordinates (θ1, φ1) and the coordinates (θ2, φ2) (S340). The control unit 140 may calculate the averages between the coordinates (θ1, φ1) and the coordinates (θ2, φ2) as the coordinates (θ, φ).

Thereafter, the control unit 140 may convert the reference coordinates from the θ/φ coordinate system back to the X/Y coordinate system. The control unit 140 may convert the coordinates (θ, φ) into the coordinates (X, Y) (S350). The following equation refers to FIG. 8.

$$\begin{matrix}X = ( R sin θ - R sin {θ}_{c} ) cos φ + ( R cos {θ}_{c} - R cos θ ) sin φ \\ Y = - ( R sin θ - R sin {θ}_{c} ) sin φ + ( R cos {θ}_{c} - R cos θ ) cos φ\end{matrix} \qquad [ Equation 5 ]$$

Thereafter, the control unit 140 calculates an affine transformation matrix based on the coordinates (X, Y) of the first alignment key 410a (S360). Using the affine transformation matrix, the control unit 140 may geometrically transform the surface image of the mask M, eliminating any image distortion caused by the tilt of the mask M.

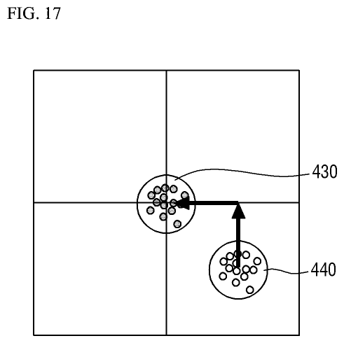

Referring to FIG. 17, if the coordinates of the first alignment key 410a are converted solely considering the affine transformation matrix, an actual position 440 of the first alignment key 410a may be displaced from an FOV center 430. FIG. 17 is an example schematic diagram for explaining the correction of a coordinate transformation formula as performed in the method of FIG. 5. Specifically, the coordinate transformation formula may be corrected to reflect the characteristics of both the spin head 221 and the swing arm 250, ensuring that the actual position 440 of the first alignment key 410a is aligned with the FOV center 430.

The control unit 140 may adjust the coordinate transformation formula by reflecting both an offset for the movement direction of the spin head 221 that results from the characteristics of the spin head 221 and an offset for the movement direction of the swing arm 250 that results from the characteristics of the swing arm 250. The control unit 140 may calculate the differences between the coordinates (θ, φ) and the coordinates (θ1, φ1) of the first alignment key 410a and set the calculated differences as θ and φ offsets (S370 in FIG. 5), but the present disclosure is not limited thereto. Alternatively, the control unit 140 may also calculate the differences between the coordinates (θ, φ) and the coordinates (θ2, φ2) of the first alignment key 410a and set the calculated differences as the θ and φ offsets.

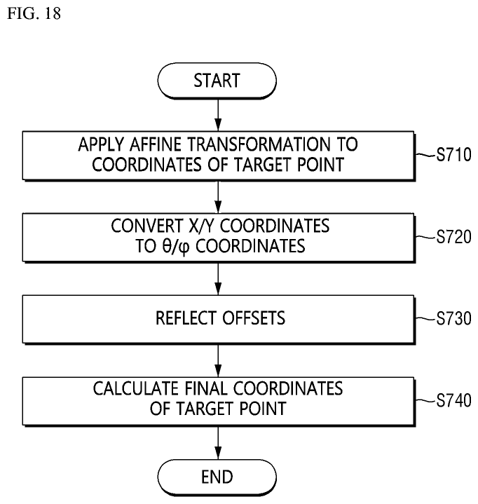

It will hereinafter be described how to convert the coordinates of a target point on the mask M into coordinates in the substrate processing apparatus 100 with the use of an alignment key. FIG. 18 is a flowchart for explaining a method of converting the coordinates of a target point on the mask to coordinates in the substrate processing apparatus. The following description refers to FIG. 18.

Referring to FIG. 18, in a case where a particular point on the mask M within the substrate processing apparatus 100 is locally heated to increase etching or cleaning efficiency or cleaning efficiency in the corresponding area, the coordinates of a target point on the mask M may be converted into coordinates in the substrate processing apparatus 100.

First, the control unit 140 calculates coordinates (X′, Y′) (S710) by applying the coordinates (X, Y) of the target point to the affine transformation matrix. The coordinates (X, Y) represent the coordinates of the target point in an original image, and the coordinates (X′, Y′) represent the coordinates of the target point in a geometrically transformed image.

Thereafter, the control unit 140 converts the coordinates (X′, Y′) in the X/Y coordinate system into coordinates (θ′, φ′) in the θ/φ coordinate system (S720). The control unit 140 may convert the coordinates (X′, Y′) into the coordinates (θ′, φ′) based on the relationship between the coordinates (X, Y) and the coordinates (θ, φ) of the first alignment key 410a.

Thereafter, the control unit 140 reflects the θ and φ offsets in the coordinates (θ′, φ′) (S730). As a result, the control unit 140 may calculate the coordinates of the target point in the substrate processing apparatus 100 (S740).

The present disclosure relates to apparatus and methods for improving the precision of the coordinates of the target point within the mask M using an affine transformation. The present disclosure achieves location accuracy for the target point within the mask M by converting from the X/Y coordinate system to the equipment-based θ/φ coordinate system and performing a correction process based on an affine transformation that reflects the mechanical characteristics of the substrate processing apparatus 100.

The present disclosure can be applied to wet etching equipment, wet cleaning equipment, etc. Specifically, the present disclosure can be applied for precisely targeting the target point on the mask M using laser beams in such equipment. However, the present disclosure is not limited to this, and may also be applicable to any equipment equipped with a swing arm and rotation chuck.

Example embodiments of the present disclosure have been described above with reference to the accompanying drawings, but the present disclosure is not limited thereto and may be implemented in other specific forms without changing the technical concept or gist of the present disclosure. Therefore, it should be understood that the embodiments set forth herein are illustrative in all respects and not limiting.

What is claimed is:

1. A substrate processing apparatus comprising:
a support unit including a spin head and configured to support and to rotate a substrate;
a spraying unit configured to spray processing liquid onto the substrate;
a correction unit in a swing arm, the correction unit configured to move to a target point on the substrate and to irradiate a beam when the processing liquid is sprayed onto the substrate; and
a control unit configured to calculate the target point,
wherein
the control unit is configured to convert image coordinates associated with a first coordinate system and then to calculate the target point by converting the image coordinates associated with the first coordinate system into image coordinates associated with a second coordinate system, and
the second coordinate system is based on rotation angles of the spin head and the swing arm.

2. The substrate processing apparatus of claim 1, wherein the control unit is configured to convert the image coordinates associated with the first coordinate system, using an affine transformation.

3. The substrate processing apparatus of claim 1, wherein the control unit is configured to calculate the target point by reflecting an offset associated with a movement direction of the spin head in the image coordinates associated with the second coordinate system.

4. The substrate processing apparatus of claim 1, wherein the control unit is configured to calculate the target point by reflecting an offset associated with a movement direction of the swing arm in the image coordinates associated with the second coordinate system.

5. The substrate processing apparatus of claim 1, wherein the control unit is configured to calculate the target point using coordinates of an alignment key installed on the substrate.

6. The substrate processing apparatus of claim 5, wherein the coordinates of the alignment key are coordinates of an alignment key with its levelness corrected with respect to a surface of the spin head.

7. The substrate processing apparatus of claim 5, wherein the control unit is configured to measure first coordinates and second coordinates of the alignment key at a first point and a second point where the alignment key intersects the swing arm, and to calculate the coordinates of the alignment key with its levelness corrected, by converting values derived from the first coordinates and the second coordinates.

8. The substrate processing apparatus of claim 7, wherein the first point is an intersection point between the swing arm and the alignment key after the swing arm passes through a center of the spin head.

9. The substrate processing apparatus of claim 7, wherein the second point is an intersection point between the swing arm and the alignment key before the swing arm passes through a center of the spin head.

10. The substrate processing apparatus of claim 7, wherein the control unit is configured to measure the first coordinates and the second coordinates as coordinates associated with the second coordinate system.

11. The substrate processing apparatus of claim 10, wherein the control unit is configured to measure the first coordinates and the second coordinates based on a rotation angle of the swing arm related to a rotation center of the spin head, a distance between the alignment key and a center of the substrate, a distance between the alignment key and an axis of rotation of the swing arm, and a rotation angle of the spin head related to the rotation center of the spin head.

12. The substrate processing apparatus of claim 7, wherein the control unit is configured to calculate averages of the first coordinates and the second coordinates.

13. The substrate processing apparatus of claim 12, wherein the control unit is configured to convert the calculated averages into coordinates associated with the first coordinate system.

14. The substrate processing apparatus of claim 5, wherein
the correction unit includes a camera sensor configured to acquire an image of the substrate, and
the control unit uses coordinates of the alignment key at a center of a Field-of-View (FOV) of the camera sensor.

15. The substrate processing apparatus of claim 14, wherein the control unit is configured to correct error associated with the rotation angle of the swing arm based on a distance between a position of the alignment key within the FOV and the center of the FOV.

16. A control device for calculating a target point on a substrate using a swing arm and a spin head, which are in a substrate processing apparatus,
wherein
the control device is configured to convert image coordinates associated with a first coordinate system, to convert the image coordinates associated with the first coordinate system into image coordinates associated with a second coordinate system, and to calculate the target point by reflecting an offset associated with a movement direction of the spin head in the image coordinates associated with the second coordinate system, and
the second coordinate system is based on rotation angles of the spin head and the swing arm.

17. The control device of claim 16, wherein the control device is configured to calculate the target point by further reflecting an offset associated with a movement direction of the swing arm in the image coordinates associated with the second coordinate system.

18. The control device of claim 16, wherein the control device is configured to convert the image coordinates associated with the first coordinate system, using an affine transformation.

19. The control device of claim 16, wherein the control device is installed in the substrate processing apparatus that processes the substrate using processing liquid.

20. A substrate processing apparatus comprising:
a support unit including a spin head and configured to support and to rotate a substrate;
a spraying unit configured to spray processing liquid onto the substrate;
a correction unit in a swing arm, the correction unit configured to move to a target point on the substrate and to irradiate a beam when the processing liquid is sprayed onto the substrate; and
a control unit configured to determine the target point,
wherein
the control unit is configured to convert image coordinates associated with a first coordinate system, using an affine transformation, to convert the image coordinates associated with the first coordinate system into image coordinates associated with a second coordinate system, and to determine the target point by reflecting an offset associated with a movement direction of the spin head and an offset associated with a movement direction of the swing arm in the image coordinates associated with the second coordinate system,
the second coordinate system is based on rotation angles of the spin head and the swing arm, and
the control unit is configured to determine the target point using coordinates of an alignment key on the substrate, by measuring first coordinates and second coordinates of the alignment key at a first point and a second point where the alignment key intersects the swing arm, and converting values derived from the first coordinates and second coordinates and thereby calculating coordinates of an alignment key with its levelness corrected.
